(19) United States
(12) Patent Application Publication
(10) Pub. No.: US 2012/0154180 A1
(43) Pub. Date: Jun. 21, 2012

(54) Light guide structure, keypad structure including the same, and method of fabricating the same

(75) Inventors: Sheng-Hsiung Chuang, Taoyuan (TW); Kuang-Hua Hsu, Taoyuan (TW)

(73) Assignee: ICHIA TECHNOLOGIES, INC., Taoyuan (TW)

(21) Appl. No.: 13/091,112

(22) Filed: Apr. 20, 2011

(30) Foreign Application Priority Data
Dec. 21, 2010 (TW) 099144904

(51) Int. Cl. H03K 17/94; G02B 6/00

(52) U.S. Cl. 341/22; 362/551

(57) ABSTRACT

A light guide structure includes a light guide layer, a light condensing structure, and a microstructure region. The light condensing structure is disposed on the light guide layer to gather light from a light source to the light guide layer for allowing the light guide layer to transmit the light. The microstructure region is disposed on the light guide layer to reflect or bend the light transmitted by the light guide layer for allowing the light to be emitted. The light condensing structure and the microstructure region are formed through a co-mold process with the light guide layer together. A keypad structure including the light guide structure and a method of fabricating the light guide structure are also disclosed.

### BACKGROUND OF THE INVENTION

1. Field of the Invention

The present invention relates to a light guide. More particularly, the present invention relates to a light guide applied in a thin keypad structure.

2. Description of the Prior Art

Electronic products such as telephones, cell phones, smart phones, personal digital assistants (PDAs), electronic translators and the like usually have keypad keyboards. For the purpose of convenience and beauty, light from a light source is required in keypad keyboard. Therefore, a light guide plate is used to transmit the light from the light source to a specific position in the keypad keyboard.

In a conventional technique, a top-view light source is applied for allowing the light to be transmitted from the bottom of the light guide plate (LGP) (also referred to as light guide film (LGF)) to the surface of the keypad. In the result, the thickness of the keypad structure mentioned above is relatively thicker. In order to meet the requirement of the thinner and smaller structure, the top-view light source is replaced by a side-view light source consisting of a light emitting diode (LED). The light generated from the side-view light emitting diode (side-view LED) is transmitted into the LGP from the side of the LGP. However, the uniformity of the light distribution is not quite even inside the LGP because the light transmitting distance in the LGP is different from one position to another position. Accordingly, as shown in FIG. 1, an LGP 2 is provided which comprises a substrate 4 having a plurality of light guide components 6 and the distribution of the light guide components is from sparse to dense, to improve the uniformity of the light distribution. Two LEDs 8 are disposed at the front side of the substrate 4.

Besides, conventionally, the pressing means of a keypad is not bonded to a conventional light guide structure when it is formed, for example, the light guide structure and a plunger are fabricated separately. The additional assembly process of the light guide structure and the plunger is necessary which results in a complicated process.

Therefore, there is still a need for a novel light guide structure and a method of fabricating the same to fabricate a relatively thin keypad structure in a convenient way.

### SUMMARY OF THE INVENTION

One objective of the present invention is to provide a molded light guide structure comprising a keypad structure and a method of fabricating the same. The molded light guide structure has a small size and is easy to be fabricated.

In one aspect, a molded light guide structure according to the present invention comprises a light guide layer, a light condensing structure, and a microstructure region. The light condensing structure is disposed on the light guide layer to gather light from a light source to the light guide layer for allowing the light guide layer to transmit the light. The light condensing structure is a co-mold with the light guide layer. The microstructure region is disposed on the light guide layer to reflect or bend the light transmitted by the light guide layer for emitting the light from the molded light guide structure. The microstructure region is a co-mold with the light guide layer.

In another aspect, a keypad structure according to the present invention comprises a substrate, a molded light guide structure mentioned above disposed above the substrate, a light source disposed beside, under, or around a corner of the light condensing structure, and a key-top structure disposed above the second face of the light guide layer.

In further another aspect, a method of fabricating a light guide structure according to the present invention comprises providing a light guide layer having a first face and a second face, providing a molding material which is light transparent after being cured, and performing a co-molding process on the light guide layer and the molding material together to mold the molding material into a light condensing structure and a microstructure region on the first face of the light guide layer.

In one preferred embodiment of the present invention, a light guide layer, a light condensing structure, and a microstructure region are co-molded together which can improve the uniformity of the light distribution in top-view structure or side-view LED structure and can allow a thinner keypad structure. In another preferred embodiment of the present invention, the light guide structure and the pressing means of the keypad structure can be together as a monolithic structure. Therefore, the keypad can be thinner and the complexity of fabricating the keypad can be reduced.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 shows a conventional light guide structure.

FIG. 2 is a schematic, three-dimensional diagram in accordance with an embodiment of the present invention.

FIG. 3 is a schematic enlarged diagram according to FIG. 2.

FIG. 4 is a schematic, cross-sectional diagram in accordance with one embodiment of the present invention.

FIGS. 5-8 are schematic, cross-sectional diagrams showing a keypad structure in accordance with some embodiments of the present invention.

FIG. 9 is a flow chart according to another embodiment of the present invention.

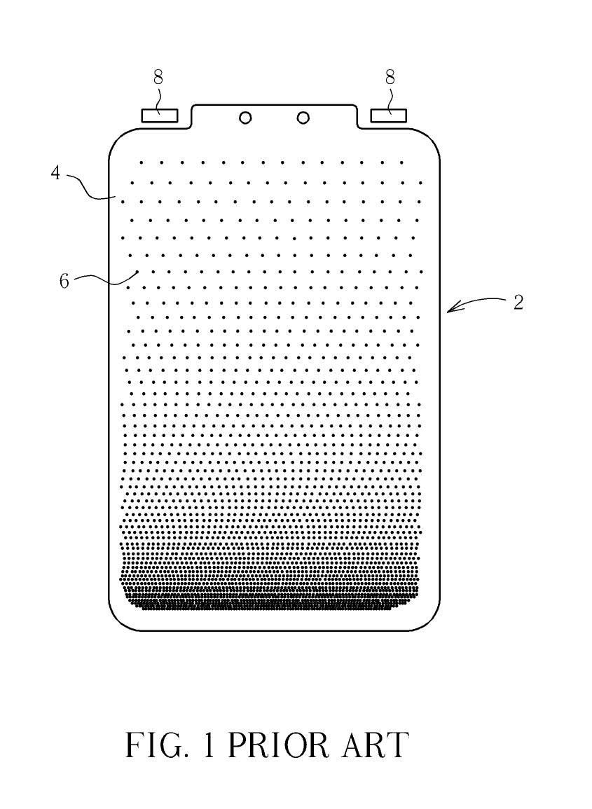

### DETAILED DESCRIPTION

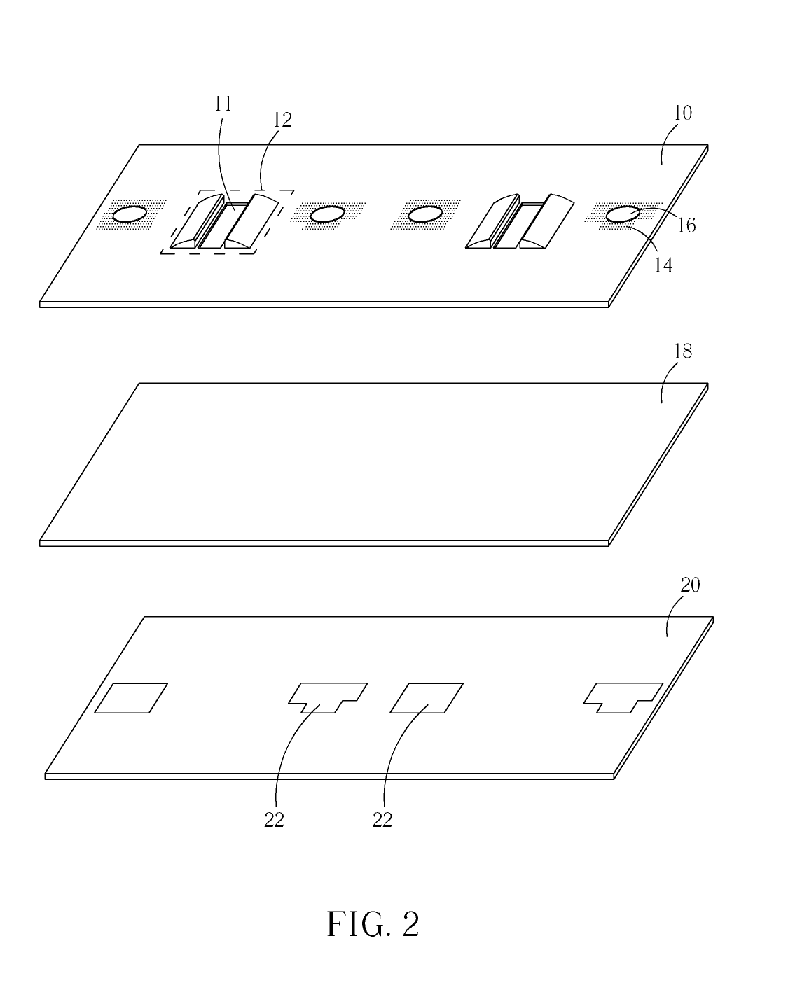

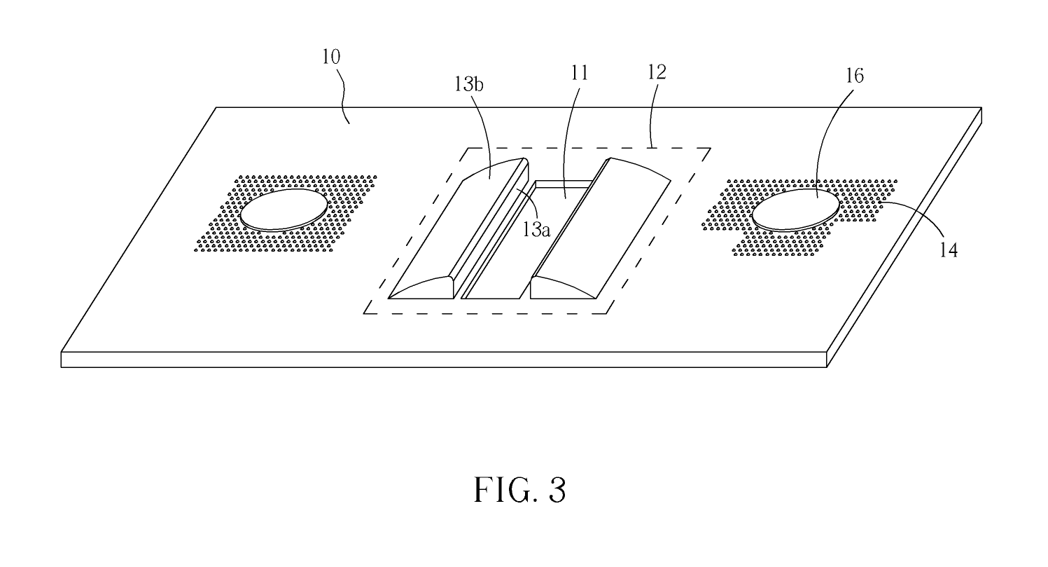

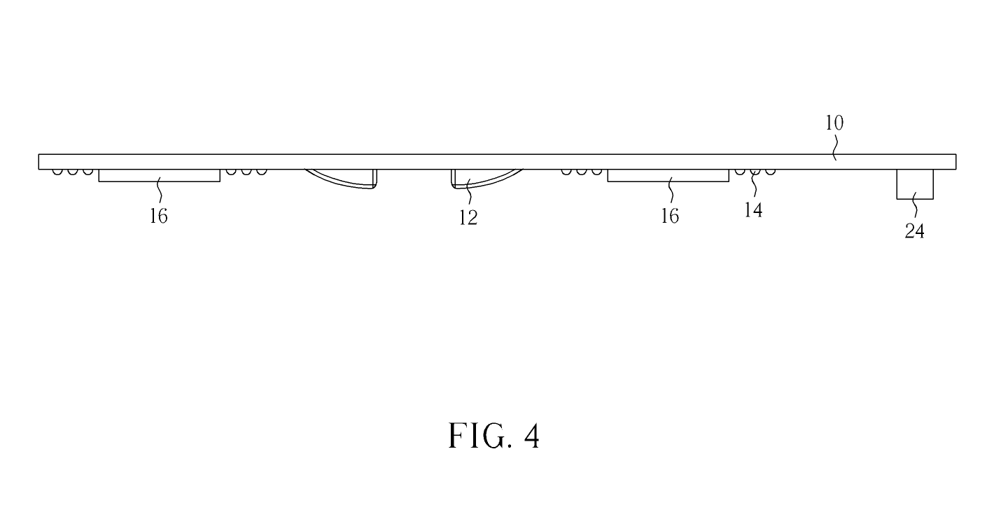

Please refer to FIG. 2 showing an exploded diagram, FIG. 3 showing a local enlarged diagram, and FIG. 4 showing a cross-sectional diagram. A molded light guide structure according to a preferred embodiment of the present invention comprises a light guide layer 10, a light condensing structure 12, and a microstructure region 14. The light guide layer 10 may be a thin film, a thin sheet or a thin plate with light guiding properties, for example, a light guide plate or a light guide film including polycarbonate (PC) material in, for example, a plate shape. A “light guide layer” mentioned in the present invention means to encompass a light guide plate and a light guide film. The light condensing structure 12 is disposed on the light guide layer 10 to gather light from a light source to the light guide layer 10 for allowing the light guide layer 10 to transmit the light. Any structure which can gather the light from the light source to the light guide layer 10 may serve as a light condensing structure in the present invention. For example, please refer to FIG. 3 showing an enlarged diagram of one preferred embodiment. The light condensing structure 12 comprises a vertical face 13a and a curved slant face 13b. One end of the vertical face 13a is disposed on the light guide layer 10, and one end of the curved slant face 13b is connected with another end of the vertical face 13a, another end of the curved slant face 13b extends slantwise and curvingly to the light guide layer 10. The curved slant face 13b may be a slant facing out and bent slightly. The vertical face 13a may serve as a receiving face to receive the light from the light source. Once the light reaches the curved slant face 13b, it can be reflected into the light guide layer 10. The light source may be LED. In consideration for fabricating a mold, the shape of the light condensing structure 12 may have a chamfer angle.

The light condensing structure 40 may comprise for example both or one of a first light condensing structure and a second light condensing structure. Both of the first light condensing structure and the second light condensing structure may comprise the vertical face 13a and the curved slant face 13b mentioned above. When the light condensing structure comprises both of the first light condensing structure and the second light condensing structure, these two structures are separated from each other and face to each other with their own vertical face 13a. However, the light condensing structure 12 is not necessary to be separated into two parts, and it may include a plurality of parts disposed around in a circle with vertical faces facing to the center of the circle, if desired.

The microstructure region 14 is disposed on the light guide layer 10 to reflect or bend the light transmitted from the light guide layer 10 for allowing the light to emit from the molded light guide structure. The microstructure region 14 may comprise any kind of tiny structures which are able to reflect or bend the light, for example, a plurality of tiny structures in sphere, hemisphere, diamond, or pyramid shape or an irregularly rough surface.

The light condensing structure 12 and the microstructure region 14 may be co-molded with the light guide layer 10, that is, the formation and the combination of the light condensing structure 12 and the microstructure region 14 with the light guide layer 10 may be achieved in one co-molding step. A material of the light condensing structure 12 and the microstructure region 14 is a kind of optical material. The choosing of the type of the optical material depends on a required function and a specific fabrication method. It is preferable to choose the molding material which meets the requirement of the light guide purpose within the entire structure and may be co-molded with the light guide layer 10, for example, a light-transparent light-curable resin (such as UV-curable resin) or light-transparent heat-curable resin (such as heat-curable silicon resin) being able to form a light-transparent light-cured resin (such as UV-cured resin) or light-transparent heat-cured resin (such as heat cured silicon rubber).

The molded light guide structure according to the present invention may be well applied in, for example, a keypad structure, and the molded light guide structure may further comprise a plunger structure if needed, for example, the plunger 16 shown in FIGS. 2-4. The plunger 16 may be co-molded with the light guide layer 10 and with the light condensing structure 12 and a microstructure region 14 together using the same molding material. Furthermore, as shown in FIG. 2, it is preferred to include a reflective layer 18 in the keypad structure to reflect the light so that more light is gathered in an emitting region and light intensity is increased. Furthermore, as shown in FIG. 2, it is preferred to have a light-shielding layer 20 to shield a particular region not requiring light. Light transparent regions 22 are disposed in the light-shielding layer 20 to emit the light. The positions of the light transparent regions 22 correspond to the positions of the plungers 16 and the microstructure regions 14. Additionally, a spacer 24 may be further disposed to maintain the distance between a light guide structure and a substrate within a keypad structure. The spacer 24 may also be co-molded with the light guide layer 10.

As shown in FIGS. 2-4, a portion of the light guide layer 10 between the first light condensing structure and the second light condensing structure of the light condensing structure 12 may be further removed, that is, to become a hollowed region 11 which may provide better light condensing properties.

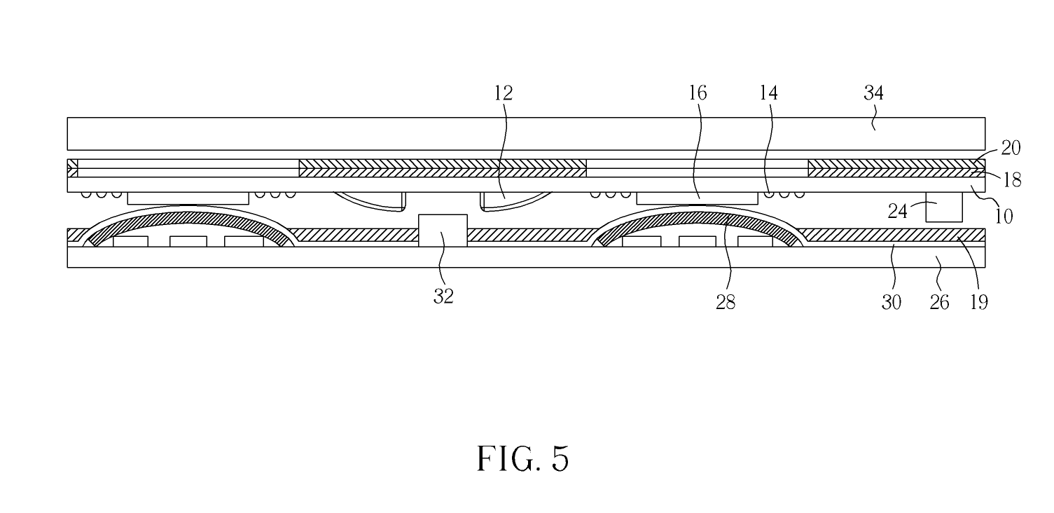

Please refer to FIGS. 5-8 illustrating some preferred embodiments of application of the molded light guide structure according to the present invention in a keypad structure. As shown in FIG. 5, according to one preferred embodiment of the invention, a keypad structure comprises a substrate 26, a molded light guide structure mentioned above disposed on the substrate 26, alight source 32 disposed below the light condensing structure 12, and a key-top structure 34 disposed above a light guide layer 10.

In a preferred embodiment, the key-top structure in the keypad structure may comprise, for example, at least one key-shaped component having a light transparent region to emit the light. The key-top structure of the present invention may comprise a conventional key pattern layer. For example, the pattern may be letters, symbols, or pictures, depending on the requirement. The pattern may be formed through a printing process or film deposition. The key-shaped component is disposed above a microstructure region to receive the light reflected or bent from the microstructure region. Both or one of the reflective layer 18 and light shielding layer 20 mentioned above may be disposed between the key-top structure 34 and the molded light guide structure. A plunger 16 mentioned above may also be disposed in the microstructure region 14 and the plunger 16 may be co-molded with the light guide layer 10. A conductive dome 28 (such as metal dome) may be disposed on the substrate 26 under the plunger 16 and the conductive dome 28 may be covered by a dome sheet 30 and fixed on the substrate 26. A reflective layer 19 may be further disposed on the substrate 26 to reflect the light emitted to the substrate 26 to the molded light guide structure. The substrate 26 may comprise a printed circuit board with printed circuit.

As shown in FIG. 5, a light source 32 disposed on a substrate 26 and under the light condensing structure 12 provides the light to the light condensing structure 12. According to this preferred embodiment, the light condensing structure 12 comprises a first light condensing structure and a second light condensing structure. There is a sufficient space (can be called a twisted space) between the first light condensing structure and the second light condensing structure to prevent the light condensing structure 12 from colliding with the light source 32 when the key is pressed, i.e. when the plunger 16 is pressed down to the conductive dome 28, to carry out relative motion of the light source 32 to the light condensing structure 12. A hollowed region 11 mentioned above in the light guide layer 10 can provide a more sufficient space for the rise of the light source 32. Therefore, the thickness of the whole keypad structure may be further lessened.

Still as shown in FIG. 5, when the light condensing structure 12 comprises only one of the first light condensing structure or the second light condensing structure, the light source 32 disposed on the substrate 26 may be located around the corner of the light condensing structure.

The light source 32 mentioned above belongs to a top-view light source. The light emitted from the top face of the light source 32 is received by a vertical face of the light condensing structure 12 which gathers the light to the light guide layer 10.

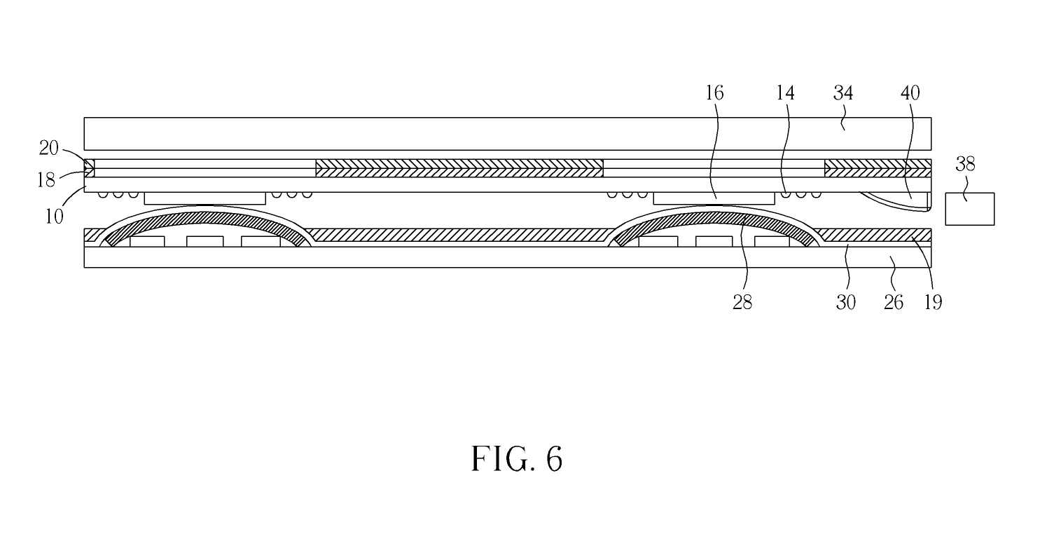

As shown in FIG. 6, according to another preferred embodiment, a light source 38 is disposed at one side of a light condensing structure 40. The light source is a side-view light source which emits the light from the side and the light is received by a vertical face of the light condensing structure 40. The light condensing structure 40 gathers the light to a light guide layer 10.

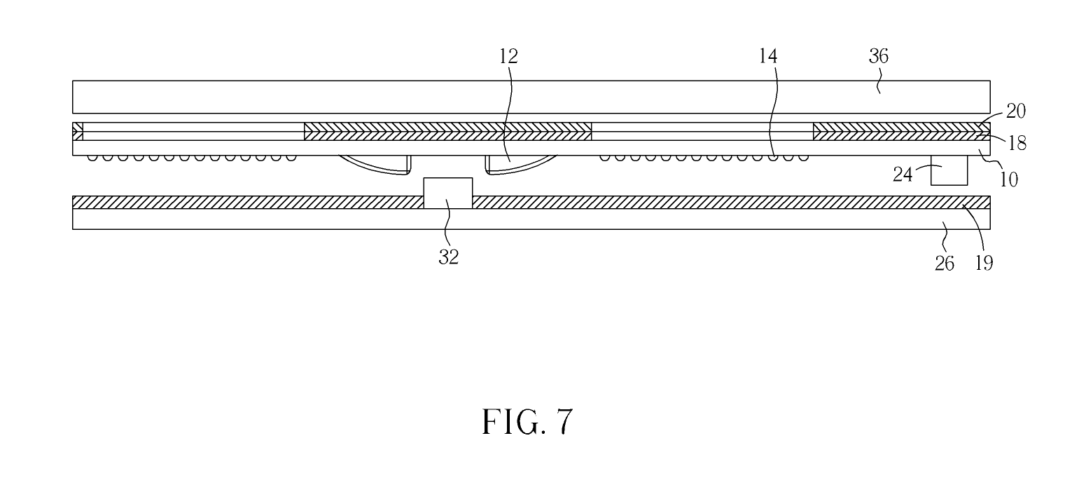

FIG. 7 illustrates a top-view light source 32 according to the preferred embodiment related to FIG. 5, but, a key-top structure 36 may comprise a touch panel and a pattern layer. The pattern layer provides desired pattern(s) for key(s) and is disposed between the touch panel and the light guide layer 10. The pattern layer may comprise light transparent regions to emit the light. The light transparent regions are preferably disposed above the microstructure regions 14. In another aspect, a key-top structure may comprise a touch panel and a liquid crystal display panel. The liquid crystal display panel is disposed between the touch panel and a light guide layer to provide pattern(s) for key(s). Therefore, the plunger 16 may be omitted. Hence, none of a conductive dome, a dome sheet, and a printed circuit is disposed on the substrate 26, but a reflective layer 19 can still be disposed.

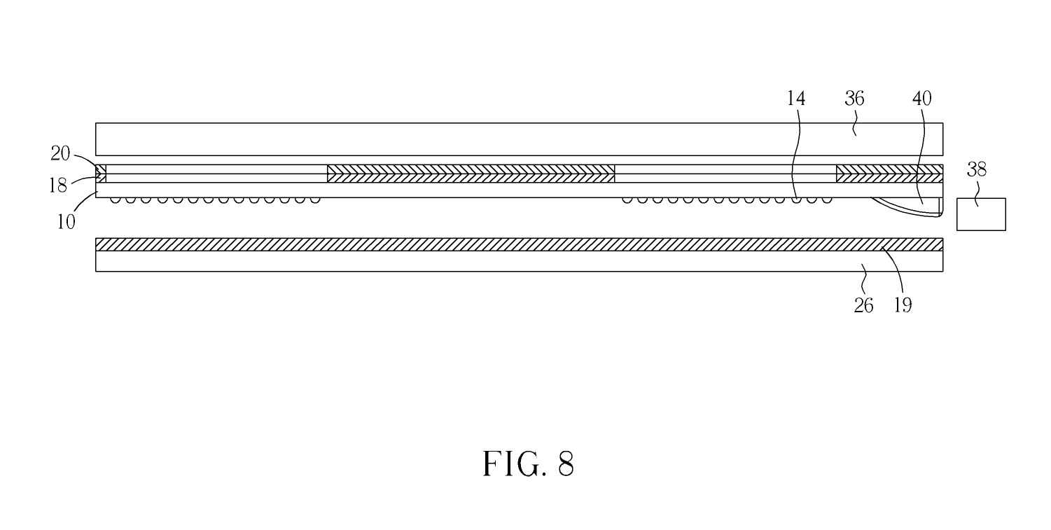

FIG. 8 illustrates a keypad structure including the key-top structure 36 including a touch panel mentioned above, but a side-view light source 38 is applied.

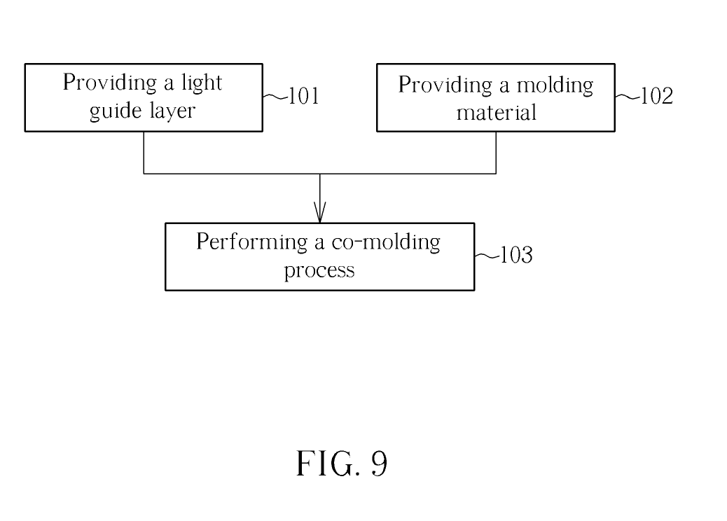

In another aspect of the present invention, a method of fabricating a light guide structure is provided. Please refer to a flow chart as shown in FIG. 9. First, a light guide layer and a molding material are provided in Steps 101 and 102. Then, in Step 103, the co-molding process is performed to co-mold the light guide layer and the molding material so that the molding material forms a light condensing structure and a microstructure region on the light guide layer. For more detailed description, the molding material is filled into the concaves of the mold which have the specific shape of the light condensing structure and the microstructure region. The mold filled with the molding material is contacted with or pressed onto a light guide layer and the molding material in the concaves is cured through a radiation process or a heat treatment. Therefore, the light condensing structure and the microstructure region is formed and firmly adhered to the light guide layer simultaneously. The as-molded structure may be further dried up if needed (in the case of UV curing, the drying process is usually required). Then, the mold is removed and a molded light guide structure is formed.

When a plunger is desired, it may be formed utilizing molding material simultaneously with the formation of a light condensing structure and a microstructure region on the light guide layer at the same side with the light condensing structure and the microstructure region. In addition, both or one of a reflective layer and a shielding layer is disposed on another side of the light guide layer. The reflective layer or the light-shielding layer may be formed through a printing process or a film deposition. A carrier plate may be applied to support a molded light guide structure, and the carrier plate is removed away in the following keypad assembling process.

In the button type keypad structure, a circuit board module may be further disposed at the same side of a light condensing structure on the light guide layer. The circuit board module comprises a printed circuit, a light source, a conductive dome, a dome sheet, and other parts as desired.

According to one preferred embodiment of the present invention, a method for fabricating the light guide structure may further comprise performing a punch process to partially remove a portion of the light guide layer beside the light condensing structure to give a hallowed region. In addition, according to the present invention, it is convenient for the fabrication that a plurality of light condensing structures, microstructure regions, and/or plungers may be formed through a co-molding process with a large sheet of a light guide layer to form a plurality of co-molded light guide structures. A punch process is then applied to the light guide structure mentioned above to give several separate molded light guide structures. A punch process forming the hollowed region may be combined with the punch process giving the shape of the light guide structure to facilitate the fabrication of the light guide structure.

Those skilled in the art will readily observe that numerous modifications and alterations of the device and method may be made while retaining the teachings of the invention.

What is claimed is:

1. A molded light guide structure, comprising:
a light guide layer;
a light condensing structure disposed on the light guide layer to gather a light from a light source to the light guide layer for allowing the light guide layer to transmit the light, wherein the light condensing structure is a co-mold with the light guide layer; and
a microstructure region disposed on the light guide layer to reflect or bend the light transmitted by the light guide layer for emitting the light from the molded light guide structure, wherein the microstructure region is a co-mold with the light guide layer.

2. The molded light guide structure according to claim 1, wherein the light condensing structure comprises a vertical face and a curved slant face, one end of the vertical face is located on the light guide layer, one end of the curved slant face connects with another end of the vertical face, and another end of the curved slant face extends slantwise and curvingly to the light guide layer.

3. The molded light guide structure according to claim 1, wherein the light condensing structure comprises a first light condensing structure and a second light condensing structure, each of the first light condensing structure and the second light condensing structure comprises a vertical face and a curved slant face, one end of each vertical face is located on the light guide layer, one end of each curved slant face connects with another end of each vertical face, another end of each curved slant face extends slantwise and curvingly to the light guide layer, and the first light condensing structure and the second light condensing structure are separated from each other and opposite to each other with each of the vertical faces.

4. A keypad structure, comprising:
a substrate;
a molded light guide structure disposed above the substrate and comprising:
a light guide layer having a first face and a second face, the first face facing the substrate,
a light condensing structure disposed on the first face of the light guide layer to gather a light to the light guide layer for allowing the light guide layer to transmit the light, wherein the light condensing structure is a co-mold with the light guide layer, and a microstructure region disposed on the first face of the light guide layer to reflect or bend the light transmitted by the light guide layer for emitting the light from the molded light guide structure, wherein the microstructure region is a co-mold with the light guide layer;
a light source disposed beside, under, or around a corner of the light condensing structure to provide the light to the light condensing structure; and
a key-top structure disposed above the second face of the light guide layer.

5. The keypad structure according to claim 4, further comprising a reflective layer disposed on the second face of the light guide layer or the substrate.

6. The keypad structure according to claim 4, further comprising a light-shielding layer disposed between the second face of the light guide layer and the key-top structure.

7. The keypad structure according to claim 4, wherein the light condensing structure comprises a vertical face and a curved slant face, one end of the vertical face is located on the light guide layer, one end of the curved slant face connects with another end of the vertical face, another end of the curved slant face extends slantwise and curvingly to the light guide layer, and the light source is disposed beside the vertical face of the light condensing structure, or around a corner of the light condensing structure.

8. The keypad structure according to claim 4, wherein the light condensing structure comprises a first light condensing structure and a second light condensing structure, each of the first and the second light condensing structures comprises a vertical face and a curved slant face, one end of each vertical face is located on the light guide layer, one end of each curved slant face connects with another end of each vertical face, another end of each curved slant face extends slantwise and curvingly to the light guide layer, and the first light condensing structure and the second light condensing structure are separated from each other and opposite to each other with each of the vertical faces, and the light source is disposed under the light condensing structure and around a corner of one of the first and the second light condensing structures.

9. The keypad structure according to claim 7, wherein a portion of the light guide layer above the light source is hollowed.

10. The keypad structure according to claim 8, wherein a portion of the light guide layer above the light source is hollowed.

11. The keypad structure according to claim 4, wherein the key-top structure comprises at least one key-shaped component comprising a light transparent region to emit the light, the key-shaped component is disposed above the microstructure region, and the keypad structure further comprises:
a plunger disposed in the microstructure region, wherein the plunger is a co-mold with the light guide layer; and
a metal dome disposed on the substrate under the plunger;
wherein the substrate comprises a printed circuit board.

12. The keypad structure according to claim 4, wherein the key-top structure comprises a touch panel and a pattern layer disposed between the touch panel and the light guide layer, the pattern layer comprises a light transparent region to emit the light, and the light transparent region is disposed above the microstructure region.

13. The keypad structure according to claim 4, wherein the key-top structure comprises a touch panel and a liquid crystal display panel disposed between the touch panel and the light guide layer to provide patterns for keys.

14. A method for fabricating a light guide structure, comprising:
providing a light guide layer having a first face and a second face;
providing a molding material, the molding material is light transparent after being cured; and
performing a co-molding process on the light guide layer and the molding material together to mold the molding material into a light condensing structure and a microstructure region on the first face of the light guide layer.

15. The method according to claim 14, further comprising:
molding the molding material into a plunger structure on the first face of the light guide layer simultaneously with the formation of the light condensing structure and the microstructure region.

16. The method according to claim 14, further comprising:
disposing a reflective layer or a light-shielding layer on the second face of the light guide layer.

17. The method according to claim 14, wherein the co-molding process comprises a curing step.

18. The method according to claim 14, further comprising performing a punch process to partially remove a portion of the light guide layer beside the light condensing structure.

19. The method according to claim 14, further comprising performing a punch process to partially remove a portion of the light guide layer beside the light condensing structure and to give a shape to the light guide structure.

20. The method according to claim 15, further comprising:
disposing a circuit board module facing the first face of the light guide layer, wherein the circuit board module comprises a printed circuit, a light source, a conductive dome and a dome sheet.
